(19) United States
(12) Patent Application Publication
(10) Pub. No.: US 2009/0288852 A1
(43) Pub. Date: Nov. 26, 2009

(54) Electronic device and method of manufacturing the same

(75) Inventors: Tomoaki Hirokawa, Kanagawa (JP); Makoto Matsunoshita, Kanagawa (JP); Yuji Kakuta, Kanagawa (JP); Naoki Sakura, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/385,994

(22) Filed: Apr. 27, 2009

(30) Foreign Application Priority Data
May 20, 2008 (JP) 2008-131991

(51) Int. Cl. H05K 5/06; B29C 65/00; B32B 37/00; B32B 7/12

(52) U.S. Cl. 174/50.52; 156/297; 156/325; 156/327; 156/250

(57) ABSTRACT

An electronic device of the present invention has a substrate; an electro-conductive pattern (electrodes) provided over the substrate; a semiconductor chip mounted over the substrate, and electrically connected with the electrodes; a resin cap provided over the substrate and composed of two or more resin layers to hollow-sealing the semiconductor chip; and an adhesive layer (metal-resin adhesion maintenance layer) bonding the resin cap with the electrode.

This application is based on Japanese patent application No. 2008-131991 the content of which is incorporated hereinto by reference.

### BACKGROUND

1. Technical Field

The present invention relates to an electronic device configured to hollow-seal an electronic component, and a method of manufacturing the same.

2. Related Art

Recent demands on higher performance, higher quality, smaller size and lower price of electronic devices have raised essential needs of improvement and sophistication of not only the devices per se, but also packages surrounding the devices. In particular for those used in the microwave region at frequencies of 20 GHz or higher, it is extremely difficult to develop small-sized, low-price packages excellent in the electrical performances and air-tightness. The packages may, therefore, expand their applications if the performances and quality durable under applications in the microwave region may be achieved only with inexpensive resin materials.

In general, when an electromagnetic wave propagates through a substance, higher-frequency wave component results in larger attenuation of energy. For this reason, high-frequency instruments such as those used for BS/CS broadcasting, microwave communication, radar and so forth adopt a configuration in which portions of electrodes of semiconductor devices and the portions of wire bonding drawn therefrom are surrounded to keep them in a hollow space in an air-tight manner.

A semiconductor device described in Japanese Laid-Open Patent Publication No. 62-40750 has, as illustrated in FIG. 6, a ceramic substrate 1, a metallized surface 3 formed over the ceramic substrate 1, and outwardly drawn leads 4, 5. A semiconductor chip 2 is mounted on the metallized surface 3, and thin metal wires 6, 7 electrically connect the semiconductor chip 2 with the outwardly drawn lead 4, 5. These components are encapsulated by a hollow ceramic cap 8, while placing adhesive resin layers 9, 10 in between. The entire portion of the hollow ceramic cap 8 is further covered with a resin layer 11.

Japanese Laid-Open Patent Publication No. 62-40750 describes that, according to the semiconductor device having this sort of hollow structure, excellent high-frequency characteristics may be ensured by virtue of absence of resin around the semiconductor chip, and that moisture resistance may be improved by virtue of a long path of leakage from the outside to the inside.

A semiconductor device described in Japanese Laid-Open Patent Publication No. 2002-110833 has, as illustrated in FIG. 7, a support substrate 21, an island portion 22 and electrodes 23 formed over the support substrate 21, a semiconductor chip 25 fixed on the island portion 22, wires 40 electrically connecting the electrodes 23 and the semiconductor chip 25, and a resin cap 28 forming therein an air-tight hollow portion 32 so as to encapsulate these components. An adhesive portion 34 where the resin cap 28 and the support substrate 21 are adhered has a trench 35 formed using a dicing blade.

Japanese Laid-Open Patent Publication No. 2002-110833 describes that the support substrate 21 and the resin cap 28 may stably be adhered by filling up the trench 35 with an adhesive resin 31, and thereby the air-tightness of the air-tight hollow portion 32 may be maintained.

However, the prior arts described in the documents in the above have been remained for further improvement, from the viewpoints described below.

The structure described in Japanese Laid-Open Patent Publication No. 62-40750, having the hollow ceramic cap 8 bonded to the leads 4, 5, was often suffering from a tendency of lowering in the adhesiveness. Another problem arose in that the adhesiveness between the hollow ceramic cap 8 and the resin layer 11 could occasionally be degraded, due to difference in the coefficient of thermal shrinkage of the hollow ceramic cap 8 and the resin layer 11.

As a consequence, the hollow ceramic cap 8 could not maintain the air-tightness inside thereof, and the situation occasionally resulted in intrusion of moisture into the ceramic cap 8, or intrusion of solder flux or the like in the process of mounting the electronic device. In particular, the solder flux occasionally lowered the yield ratio of product, since it may creep on the metal component along with heat conduction.

Moreover, it has been difficult to apply the ceramic cap to BS/CS broadcasting, microwave communication instrument, radar instrument and so forth, due to stringent demand on cost.

On the other hand, the structure described in Japanese Laid-Open Patent Publication No. 2002-110833 has occasionally resulted in complication of the processes, because it has been necessary to provide the trench on the substrate side, and also because a desirable level of accuracy has been necessary in alignment between the resin cap 28 and the support substrate 21.

### SUMMARY

According to the present invention, there is provided an electronic device which includes:

a substrate;

an electro-conductive pattern provided over the substrate;

an electronic component mounted over the substrate, and electrically connected to the electro-conductive pattern;

a resin cap provided over the substrate, and composed of two or more resin layers hollow-sealing the electronic component; and

an adhesive layer bonding the resin cap with the electro-conductive pattern.

Since the resin cap composed of two or more resin layer is used for hollow-sealing the electronic component in the present invention, so that separation between the layers due to difference in the coefficient of thermal shrinkage may be suppressed. The resin cap composed of two or more resin layers is also advantageous in that, even if one resin layer composing the resin cap should accidentally have a pinhole formed therein, influences thereof may be suppressed by the other resin layer(s).

In the present invention, the adhesive layer (metal-resin adhesion maintenance layer) bonding the resin cap and the electro-conductive pattern is adopted. Accordingly, the resin cap may be suppressed from separating from the adhesive layer due to difference between the inner pressure and outer pressure of the resin cap ascribable to difference in temperature in the process of encapsulation with the resin cap, and thereby the air-tightness around the electronic component may be maintained.

The yield ratio of product may thus be improved.

The cap made of a resin may suppress the cost of manufacturing, as compared with the cap made of a ceramic.

According to the present invention, there is provided also a method of manufacturing an electronic device which includes:

preparing a substrate having an electro-conductive pattern formed thereon;

forming an adhesive layer over the electro-conductive pattern provided over the substrate;

mounting an electronic component over the substrate, and electrically connecting the electronic component with the electro-conductive pattern; and

bonding a resin cap composed of two or more resin layers with the electro-conductive pattern while placing the adhesive layer in between, so as to hollow-seal the electronic component.

According to the present invention, since the electronic component may be hollow-sealed by bonding the resin cap composed of two or more resin layers with the electro-conductive pattern, while placing the adhesive layer in between, so that an electronic device having the electronic component tightly hollow-sealed therein may be obtained by a simple procedure.

According to the electronic device of the present invention, the air-tightness around the electronic component may be maintained, the yield ratio of product may be improved, and the cost may be suppressed from increasing. In addition, according to the method of manufacturing an electronic device of the present invention, an electronic device having the electronic component tightly hollow-sealed therein may be obtained by a simple procedure.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view schematically illustrating a semiconductor device of an embodiment;

FIGS. 2A to 3B are schematic sectional views sequentially illustrating a method of manufacturing a semiconductor device of the embodiment;

FIG. 4 is a top view of a substrate in an embodiment;

FIG. 5 is a schematic sectional view illustrating a semiconductor device according to another embodiment;

FIG. 6 is a schematic sectional view illustrating a conventional semiconductor device; and

FIG. 7 is a schematic sectional view illustrating another conventional semiconductor device.

### DETAILED DESCRIPTION

The invention will now be described herein with reference to an illustrative embodiment. Those skilled in the art will recognize that many alternative embodiments can be accomplished using the teachings of the present invention and that the invention is not limited to the embodiment illustrated for explanatory purposes.

Embodiments of the present invention will be explained below, referring to the attached drawings. Note that any similar constituents will be given with similar reference numerals or symbols in all drawings, and explanations therefor will not be repeated.

The present invention will be explained below, referring to a first embodiment and a second embodiment.

### First Embodiment

This embodiment will be explained referring to an exemplary case where a semiconductor device was formed as the electronic device.

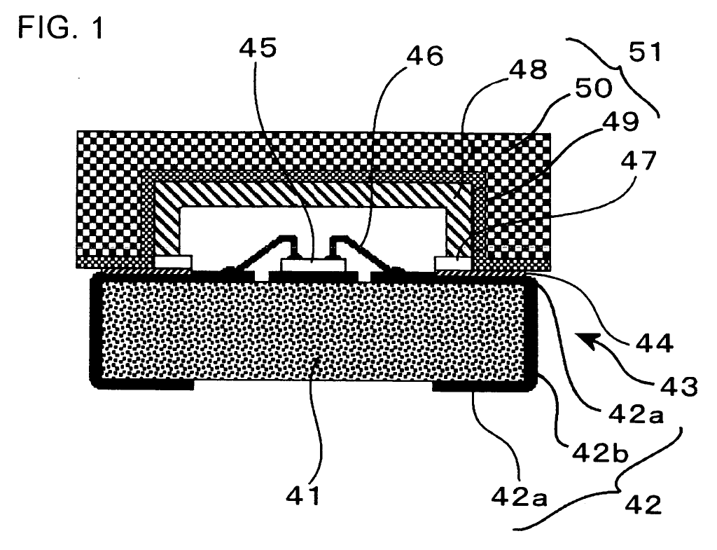

The semiconductor device of this embodiment has, as illustrated in FIG. 1, a substrate 41, an electro-conductive pattern (electrodes 42) provided over the substrate 41, an electronic component (semiconductor chip 45) mounted over the substrate 41, and electrically connected with the electrodes 42, a resin cap 51 provided over the substrate 41 so as to hollow-seal the semiconductor chip 45, and composed of three resin layers (a first resin layer 48, a second resin layer 49, and a third resin layer 50), and the adhesive layer (metal-resin adhesion maintenance layer 44) bonding the resin cap 51 with the electrodes 42.

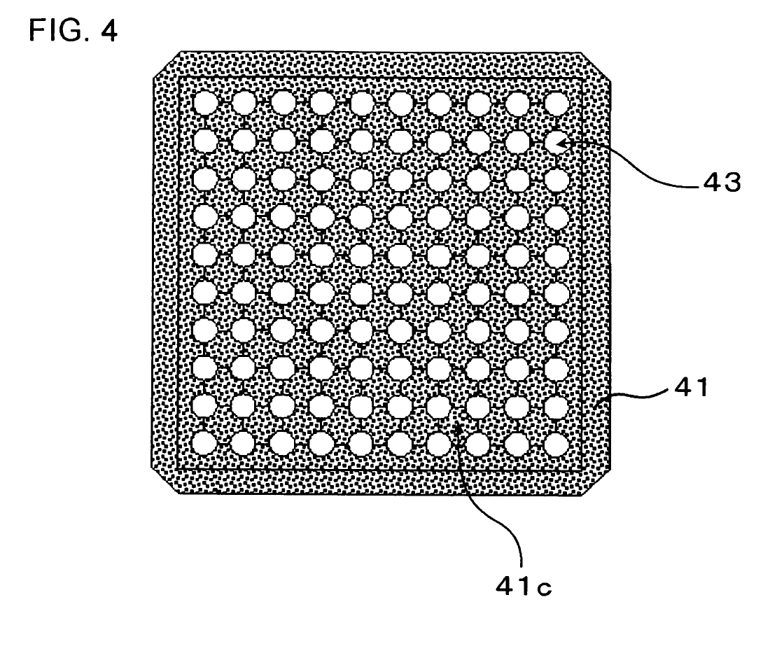

The substrate 41 adoptable to this embodiment has a plurality of through-holes (viaholes 43) as illustrated in FIG. 4. Dielectric materials such as alumina ceramics, low temperature co-fired ceramics (LTCC); resin material such as Teflon (registered trademark) and glass-epoxy composite; highly-flexible substrate and so forth may be adoptable to the substrate 41. The thickness of the substrate 41 is typically 200 μm.

On regions 41c of the substrate 41 having no viaholes formed therein, a plurality of semiconductor chips 45 are mounted. FIG. 1 illustrates a singulated chip having only a single semiconductor chip 45 mounted on the substrate 41 illustrated in FIG. 4, and obtained by dicing the substrate 41 between every adjacent semiconductor chips 45.

Each electrode 42 extends from the top surface of the substrate 41 through the viaholes 43 out onto the back surface. The electrode 42 is composed of electrodes 42a, 42a formed on both surfaces of the substrate 41, and a connection electrode 42b formed by metallizing the inner wall of the viaholes 43 formed in the substrate, and connecting the electrodes 42a, 42a.

Each semiconductor chip 45 is electrically connected through bonding wires 46 with the electrode 42a formed on the top surface of the substrate 41.

The metal-resin adhesion maintenance layer 44 may bond metal with resin. For the case where an dielectric material such as alumina ceramics, LTCC or the like is adopted to the substrate 41, alumina coated layer (inorganic layer) containing aluminum oxide may be adoptable as the metal-resin adhesion maintenance layer 44.

The alumina coated layer may be obtained in a form having a porous surface, and may therefore be bonded tightly with metals. Moreover, if the resin layer composing the resin cap 51 is made of epoxy resin, the alumina coating excellent in the surface affinity with the resin layer may be bonded tightly with the resin layer.

On the other hand, if a resin material such as Teflon (registered trademark) or glass-epoxy composite is used for the substrate 41, an organic layer containing alkyd resin as a major component may be used for the metal-resin adhesion maintenance layer 44. Resin composition containing alkyd resin as a major component may be commercially available under the name of Green Resist (from Sunhayato Corp., alkyd resin/oil-modified urethane resin base) or the like.

The adhesion maintenance layer containing alkyd resin as a major component is more excellent in the surface affinity with metals, as compared with epoxy-base resins generally used for electronic elements, and may tightly bond the electrode and the resin layer.

The resin cap 51 is composed of the first resin layer 48, the second resin layer 49, and the third resin layer 50.

The first resin layer 48 has a U-form section opened downward. The first resin layer 48 is bonded at the end portion thereof with the electro-conductive pattern, while placing the metal-resin adhesion maintenance layer 44 in between, so as to hollow-seal the semiconductor element. The first resin layer 48 may be configured by a thermosetting epoxy resin or the like, while adjusting the thickness thereof to 100 μm to 500 μm. There is further provided an adhesive resin 47 between the first resin layer 48 and the metal-resin adhesion maintenance layer 44.

The second resin layer 49 is composed of a resin film, and is formed so as to cover the opening portion of the viaholes 43 on the top surface side of the substrate 41 (FIGS. 1, 4).

The second resin layer 49 is composed of a thermosetting resin such as epoxy resin (epoxy phenol silica acrylate ester). The thickness of the second resin layer 49 is typically 20 to 150 μm, and resin flow at 50° C. is 1200 μm or smaller.

The third resin layer 50 is formed so as to cover the second resin layer 49. The third resin layer 50 is typically composed of a thermosetting resin such as epoxy-base resin. The thickness of the third resin layer 50 is 400 μm, for example.

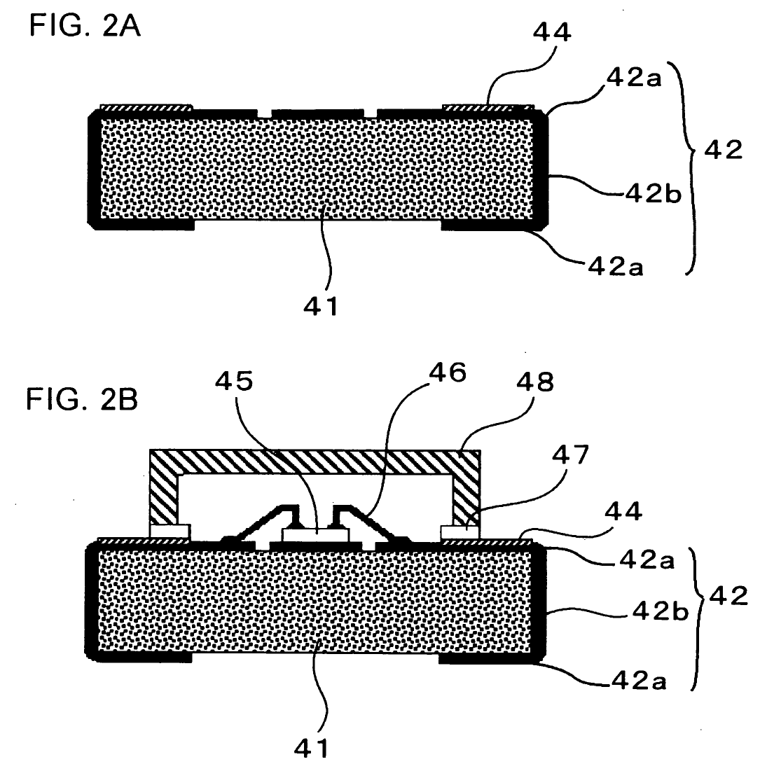

Next, an outline of the method of manufacturing an electronic device (semiconductor device) according to this embodiment will be explained referring to FIGS. 2A, 2B, 3A, 3B and 4.

The method of manufacturing a semiconductor device of this embodiment has the steps below:

(a) preparing the substrate having a plurality of through-holes (viaholes) extended therethrough in the thickness-wise direction, and having the electro-conductive pattern (electrodes) extended from the top surface thereof through the through-holes out onto the back surface thereof;

(b) forming an adhesive layer over the electrodes provided on the substrate;

(c) mounting a plurality of electronic components (semiconductor chips) onto the regions of the substrate having no through-holes formed therein, and electrically connecting the semiconductor chips with the electrodes;

(d) forming the first resin layer which bonds to the electrodes while placing the adhesive layer in between, so as to hollow-seal the semiconductor chips;

(e) forming a second resin layer covering the first resin layer and covering the opening portion of the viaholes on the top surface side of the substrate;

(f) forming the third resin layer over the second resin layer; and

(g) singulating the electronic device by dicing the substrate between every adjacent electronic components.

The method will be explained sequentially referring to the individual steps.

(a) A step of preparing the substrate having a plurality of viaholes extended therethrough in the thickness-wise direction, and having the electrodes extended from the top surface thereof through the through-holes out onto the back surface thereof.

As illustrated in FIG. 4, a plurality of viaholes 43 are formed in the periphery of regions of the substrate 41 allowed for later mounting of the semiconductor chips 45 (regions 41c having no viaholes formed therein). The viaholes 43 may be provided to the opposed (diagonal) positions along the edges of each region 41c, or may be provided at four points outside four edges of each region 41c. The inner side faces of the viaholes 43 are typically composed of a metal conductor such as gold. The individual steps described below are carried out, while keeping the substrate 41 placed on a support member having a flat top surface.

The electrodes 42a, 42a are then formed at predetermined positions on the top surface and the back surface of the substrate 41, by metallization such as PVD or CVD, and the connection electrode 42b is formed on the inner side faces of the viaholes 43 in the substrate 41 typically by metallization. The electrodes 42 are thus formed (FIG. 2A).

(b) A step of forming the adhesive layer on the electrodes provided over the substrate.

Next, the metal-resin adhesion maintenance layer 44 is formed by a predetermined method, on the electrodes 42a formed on the top surface of the substrate 41 (FIG. 2A).

(c) A step of mounting a plurality of semiconductor chips onto the regions of the substrate having no viaholes formed therein, and electrically connecting the semiconductor chips with the electrodes.

A plurality of semiconductor chips 45 are mounted onto the regions 41c having no viaholes formed therein as illustrated in FIG. 4. Pads of each semiconductor chip 45 are then connected to the electrodes 42a through bonding wires 46 as illustrated in FIG. 2B, thereby each semiconductor chip 45 is electrically connected with the electrodes 42a.

(d) A step of forming the first resin layer which bonds to the electrodes while placing the adhesive layer in between, so as to hollow-seal the semiconductor chips.

First, a box-like resin cap opened in one direction is prepared, and the adhesive resin 47 is coated on the edge of the resin cap. The resin cap is then placed on the metal-resin adhesion maintenance layer 44 so as to bring the adhesive resin 47 into contact therewith, and the resin cap is cured by heating for encapsulation. The temperature of encapsulation may be adjusted to 50 to 150° C.

In this way, the first resin layer 48 hollow-sealing each semiconductor chip 45 is formed (FIG. 2B).

(e) A step of forming a second resin layer covering the first resin layer and covering the opening portion of the viaholes on the top surface side of the substrate.

First, the entire top surface of the substrate 41 illustrated in FIG. 4 is covered with a resin film 49a. In this process, the temperature of the resin film 49a is raised to as high as approximately 50° C. so as to soften it, and the resin film 49a is brought into contact uniformly with the substrate 41, while allowing the resin film 49a to deform so as to cover the first resin layer 48 and the substrate 41.

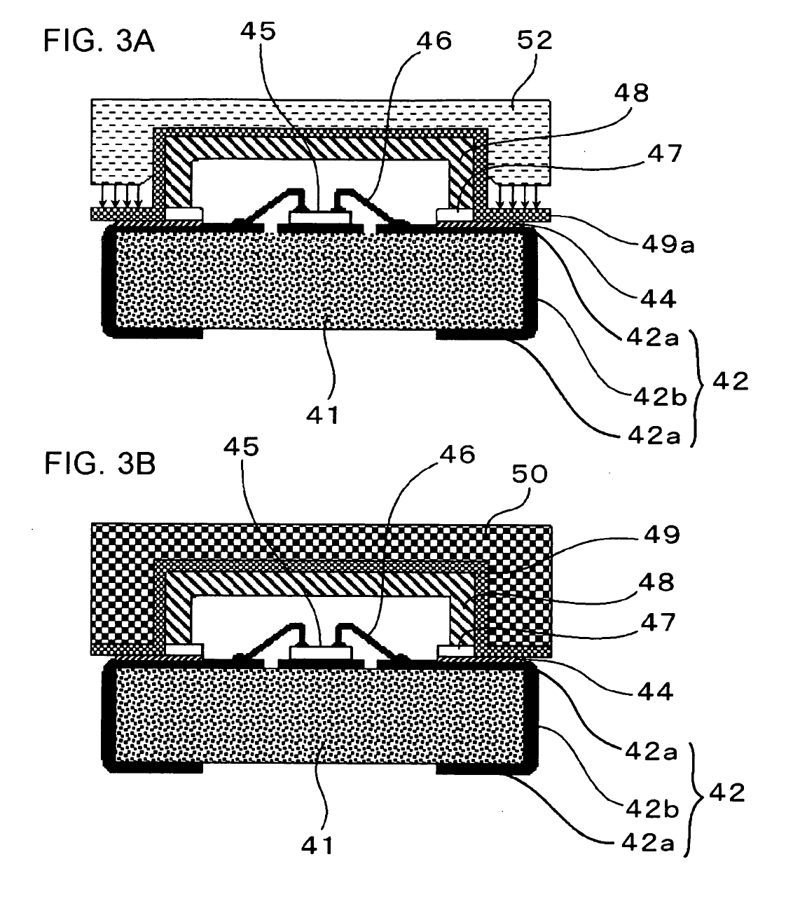

The resin film 49a is then entirely pressed from the top thereof down to the substrate 41 so as to make close contact therewith, under a pressure of 0.5 MPa or around using a crimping jig 52 composed of an elastic material such as rubber, while keeping the space between the resin film 49a and the substrate 41 evacuated to a pressure of 50 Pa or lower (FIG. 3A).

The pressure and temperature are kept unchanged until the resin film 49a is sufficiently reduced in the viscosity, and the atmosphere is returned back again to normal temperature and normal pressure. Thereafter, the temperature of the resin film 49a is elevated typically to as high as 170° C. or around so as to allow it to cure, and thereby the resin film 49a is bonded to the substrate 41 and fixed in the geometry thereof. The resin film 49a produces force of shrinkage in the process of curing. The force of shrinkage of the resin film 49a operates so as to pressurize the first resin layer 48 towards the substrate 41. In this way, mechanical bonding between the first resin layer 48 and the substrate 41 may more reliably be enhanced. By virtue of the shrinkage of the resin film 49a, the resin film 49a may more tightly bond to the first resin layer 48 and the substrate 41.

Alternatively, if the resin film 49a has a sufficient level of flexibility even under normal temperature, the resin film 49a may be deformed at normal temperature to determine the geometry, and may thereafter be allowed to cure by elevating the temperature.

Still alternatively, the geometry of the resin film 49a may be determined while being softened at a temperature not higher than the glass transition temperature, and thereafter the resin film 49a may be cured over a relatively long duration of time at a temperature not higher than the glass transition temperature.

If the resin film 49a is composed of a resin possibly softened by ultraviolet radiation, the resin film 49a may be softened by ultraviolet irradiation, in place of allowing it to soften by elevating the temperature. Still alternatively, the resin film 49a may be softened by ultraviolet irradiation, at the same time with elevation of the temperature.

If the resin film 49a is composed of a ultraviolet-curable resin, the resin film 49a may be cured by irradiating ultraviolet radiation, in place of allowing it to cure by elevating the temperature. Still alternatively, the resin film 49a may be cured by ultraviolet irradiation, at the same time with elevation of the temperature.

In this way, the second resin layer 49 is formed so as to cover the first resin layer 48 and the opening portions of the viaholes 43 on the top surface side of the substrate 41 (FIG. 3B).

(f) A step of forming the third resin layer over the second resin layer.

After the second resin layer 49 is formed, the temperature of the product is again elevated to 150° C., the top surface of the second resin layer 49 is covered with an epoxy-base resin or the like, the epoxy-base resin is pressed from the top thereof by a flat jig, and allowed to cure under heating, so as to form the third resin layer 50 (FIG. 3B). In this way, the mechanical strength of the semiconductor device as a whole may be increased, surface irregularity ascribable to the first resin layer 48 may be planarized, and thereby automated mounting may be facilitated.

(g) A step of singulating the electronic device by dicing the substrate between every adjacent electronic components.

The substrate is diced between every adjacent semiconductor chips 45 using a dicing saw or laser cutter, so as to obtain the semiconductor devices. In this embodiment, a highly-productive configuration may be realized by using a sheet-like substrate 41 capable of producing a plurality of semiconductor devices at the same time.

Effects of this embodiment will be explained.

According to the semiconductor device of this embodiment using the resin cap 51 composed of two or more resin layers formed so as to hollow-seal the semiconductor chip 45, separation between the layers ascribable to difference in the coefficient of thermal shrinkage may be suppressed. The resin cap 51 composed of two or more resin layers is also advantageous in that, even if one resin layer composing the resin cap should accidentally have a pinhole formed therein, influences thereof may be suppressed by the other resin layer(s).

In the present invention, the adhesive layer (metal-resin adhesion maintenance layer 44) bonding the resin cap 51 and the electro-conductive pattern (electrodes 42) is adopted. Accordingly, the resin cap 51 may be suppressed from separating from the metal-resin adhesion maintenance layer 44 due to difference between the inner pressure and outer pressure of the resin cap 51 ascribable to difference in temperature in the process of encapsulation with the resin cap 51, and thereby the air-tightness of the space surrounding the semiconductor chip may be maintained.

In this way, intrusion of solder flux or moisture into the resin cap 51, in the process of mounting the semiconductor chips, may exactly be avoidable.

Adoption of the multi-layer structure of the resin cap 51 also facilitates automated mounting, by virtue of improvement in the strength of semiconductor devices in the vertical direction.

In this embodiment, the second resin layer 49 covers the opening portions of the viaholes 43 on the top surface side of the substrate 41.

Accordingly, in the process of forming the third resin layer 50, the resin is suppressed from creeping onto the back surface of the substrate 41 through the viaholes 43, and thereby the yield ratio of product may be improved.

### Second Embodiment

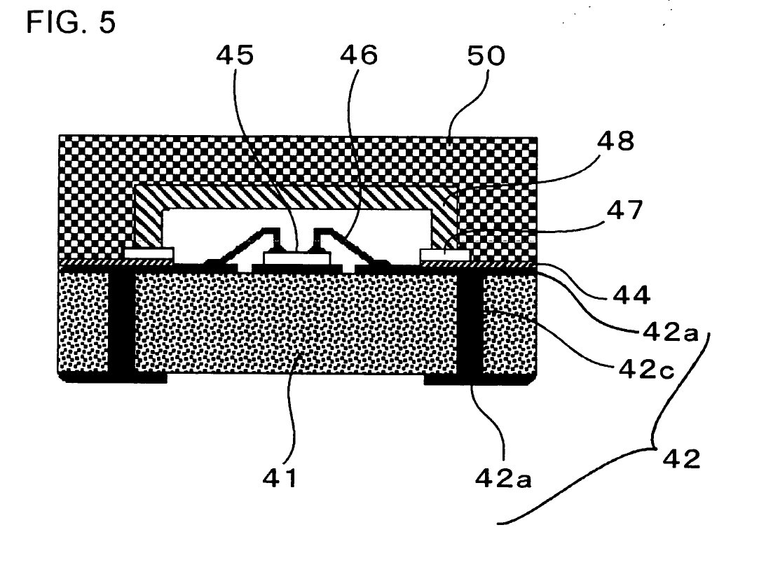

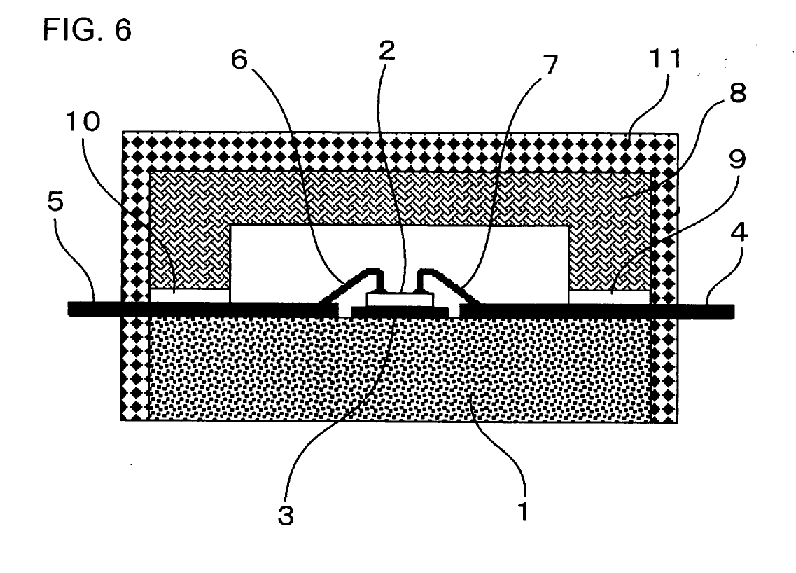

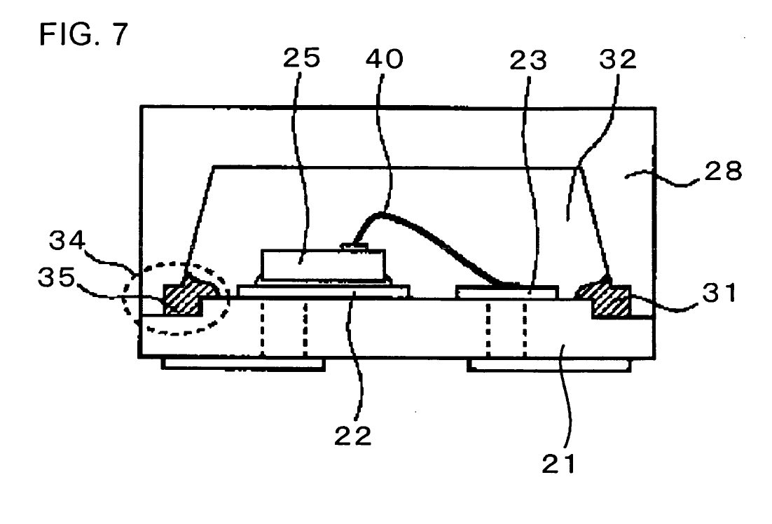

Next, a configuration of an electronic device according to a second embodiment of the present invention will be explained, referring to FIG. 5.

The semiconductor device of this embodiment has the electrodes 42a, 42a exposed to both surfaces of the substrate 41, wherein the electrodes 42a, 42a are connected through the via-filling metallized layers 42c.

Accordingly, the resin used in the first embodiment for forming the third resin layer 50 may be prevented from creeping onto the back surface, so that the second resin layer 49 is no more necessary, and thereby the structure may be simplified. Therefore, the semiconductor device having a semiconductor chip reliably hollow-sealed therein may be obtained by a further simplified method.

The embodiments of the present invention have been described referring to the attached drawings, merely as exemplary cases of the present invention, while allowing adoption of various configurations other than those described in the above.

The resin cap 51 in the first embodiment, explained as the one configured by three resin layers, may be configured by four or more resin layers.

The electronic devices explained in these embodiments, having the semiconductor chips as the electronic component, may alternatively have other electronic component such as GaAs FET, oscillator, high-frequency circuit components or the like.

It is apparent that the present invention is not limited to the above embodiments, that may be modified and changed without departing from the scope and spirit of the invention.

What is claimed is:

1. An electronic device comprising:
a substrate;
an electro-conductive pattern provided over said substrate;
an electronic component mounted over said substrate, and electrically connected to said electro-conductive pattern;
a resin cap provided over said substrate, and composed of two or more resin layers hollow-sealing said electronic component; and
an adhesive layer bonding said resin cap with said electro-conductive pattern.

2. The electronic device as claimed in claim 1,
wherein said adhesive layer is an inorganic layer containing aluminum oxide, or an organic layer containing alkyd resin.

3. The electronic device as claimed in claim 1,
wherein said substrate has a through-hole extended therethrough in the thickness-wise direction,
said electro-conductive pattern is extended from the top surface of said substrate through said through-hole out onto the back surface, and
said resin cap comprises:
a first resin layer bonded to said electro-conductive pattern while placing said adhesive layer in between so as to hollow-seal said electronic component;
a second resin layer covering said first resin layer; and
a third resin layer covering said second resin layer.

4. The electronic device as claimed in claim 3,
wherein said second resin layer covers an opening of said through-hole on the top surface side of said substrate.

5. The electronic device as claimed in claim 3,
wherein said second resin layer is composed of a resin film.

6. The electronic device as claimed in claim 1,
wherein said electronic component operates at high frequencies.

7. The electronic device as claimed in claim 1, obtained by singulation between every adjacent electronic components mounted on said substrate.

8. A method of manufacturing an electronic device comprising:
preparing a substrate having an electro-conductive pattern formed thereon;
forming an adhesive layer over said electro-conductive pattern provided over said substrate;
mounting an electronic component over said substrate, and electrically connecting said electronic component with said electro-conductive pattern; and
bonding a resin cap composed of two or more resin layers with said electro-conductive pattern while placing said adhesive layer in between, so as to hollow-seal said electronic component.

9. The method of manufacturing an electronic device as claimed in claim 8
wherein said forming said adhesive layer further comprises:
forming an adhesive layer composed of either an inorganic layer containing aluminum oxide, or an organic layer containing alkyd resin.

10. The method of manufacturing an electronic device as claimed in claim 8,
wherein said preparing said substrate further comprises:
preparing a substrate having a plurality of through-holes extended therethrough in the thickness-wise direction, and having an electro-conductive pattern extended from the top surface thereof through said through-holes out onto the back surface thereof,
wherein said electrically connecting said electronic component with said electro-conductive pattern further comprises:
mounting a plurality of said electronic components onto regions of said substrate having no through-holes formed therein, and
said hollow-sealing said electronic component further comprises:
forming a first resin layer which bonds to said electro-conductive pattern while placing said adhesive layer in between, so as to hollow-seal said electronic component;
forming a second resin layer over said first resin layer; and
forming a third resin layer over said second resin layer.

11. The method of manufacturing an electronic device as claimed in claim 10,
wherein said forming said second resin layer further comprises:
forming said second resin layer which covers said first resin layer, and covers also the opening of said through-hole over the top surface side of said substrate.

12. The method of manufacturing an electronic device as claimed in claim 11,
wherein said forming said second resin layer further comprises:
covering the entire top surface of said substrate with said second resin layer composed of a resin film, and bonding said second resin layer with said substrate while pressurizing it towards the top surface of said substrate.

13. The method of manufacturing an electronic device as claimed in claim 8, further comprising, after said hollow-sealing said electronic components,
singulating the electronic device by dicing said substrate between every adjacent electronic components.
